(19) United States
(12) Patent Application Publication
(10) Pub. No.: US 2004/0005781 A1
(43) Pub. Date: Jan. 8, 2004

(54) HDP SRO liner for beyond 0.18 um STI gap-fill

(75) Inventors: Liu Huang, Singapore (SG); Han Sang Hyun, Singapore (SG); John Sudijono, Singapore (SG); Jia Zhen Zheng, Singapore (SG); Alan Cuthbertson, Singapore (SG)

Correspondence Address: GEORGE O. SAILE & ASSOCIATES, 28 DAVIS AVENUE, POUGHKEEPSIE, NY, 12603, US

(73) Assignee: Chartered Semiconductor Manufacturing Ltd.

(21) Appl. No.: 10/187,703

(22) Filed: Jul. 2, 2002

(51) Int. Cl. H01L 21/311

(52) U.S. Cl. 438/694

(57) ABSTRACT

A new method of forming shallow trench isolations is described. An isolation trench is etched into a substrate. A silicon-rich oxide liner layer is deposited overlying the substrate and within the isolation trench using a high density plasma chemical vapor deposition process (HDP-CVD). Then, an oxide layer is deposited by HDP-CVD overlying the silicon-rich oxide liner layer and filling the trench to complete fabrication of said shallow trench isolation region in the manufacture of the integrated circuit device. The silicon-rich oxide liner layer is of high quality and has a high wet etch rate thereby minimizing divots formed during cleaning steps.

### BACKGROUND OF THE INVENTION

(1) Field of the Invention

The invention relates to a method of fabricating semiconductor structures, and more particularly, to a method of forming shallow trench isolation structures without leakage in the manufacture of integrated circuit devices.

(2) Description of the Prior Art

Shallow trench isolation (STI) is now commonly used in the art as an alternative to local oxidation of silicon (LOCOS) for forming isolations between active device areas in the integrated circuit. STI offers the advantages of smaller isolation area and better surface planarization when compared to LOCOS. High density plasma chemical vapor deposition (HDP-CVD) has become the dominant process for STI trench gap-fill. Since HDP oxide forms by the reaction between SiH₄ and O₂ under high density plasma (10¹¹ to 10¹³ ions/cm³) with simultaneous Ar or He bombardment for sputtering, the oxide has higher H₂ concentration than thermal oxide. Also the quality of HDP oxide, especially the quality of an in-situ undoped silicate glass (USG) liner is not so good as that of the thermal oxide in terms of wet etch rate. So, after HDP gap-filling, high temperature N₂ or O₂ annealing follows, in general. However, this high temperature anneal generates some physical defects at the bottom corners of the trench, resulting in leakage problems. On the other hand, since the wet etch rate of as-deposited HDP oxide is greater than that of thermal oxide, the further dilute hydrofluoric acid (DHF) cleaning processes cause oxide recessing at the top corner of the trench, resulting in a physical divot, which may cause leakage problems in the junctions. It is desired to both improve the quality of the liner layer and to minimize the physical divot at the top corner of the trench.

Several prior art approaches disclose methods to form shallow trench isolations. U.S. Pat. Nos. 5,968,610 to Liu et al and 6,203,863 to Liu et al show a process in which a silicon rich oxide layer is deposited as a first step in an HDP-CVD gap-filling process. However, this is a metal wiring gap-fill process, requiring much lower temperatures than an STI gap fill process. U.S. Pat. No. 5,726,090 to Jang et al shows a thermal oxide liner layer, then a deposited TEOS layer for gap-filling.

### SUMMARY OF THE INVENTION

A principal object of the present invention is to provide an effective and very manufacturable method of fabricating shallow trench isolations in the manufacture of integrated circuits.

A further object of the present invention is to provide a method to fabricate shallow trench isolations having a high quality liner layer to prevent bottom leakage.

Another object of the present invention is to provide a method to fabricate shallow trench isolations while minimizing the physical divot at the top corner of the trenches.

Yet another object of the invention is to provide a method to fabricate shallow trench isolations having an in-situ silicon-rich oxide liner layer.

In accordance with the objects of this invention, a new method of forming shallow trench isolations is achieved. An isolation trench is etched into a substrate. A silicon-rich oxide liner layer is deposited overlying the substrate and within the isolation trench using a high density plasma chemical vapor deposition process (HDP-CVD). Then, an oxide layer is deposited by HDP-CVD overlying the silicon-rich oxide liner layer and filling the trench to complete fabrication of a shallow trench isolation region in the manufacture of the integrated circuit device. The silicon-rich oxide liner layer is of high quality and has a high wet etch rate thereby minimizing divots formed during cleaning steps.

### BRIEF DESCRIPTION OF THE DRAWINGS

In the accompanying drawings forming a material part of this description, there is shown:

FIGS. 1 through 4 schematically illustrate in cross-sectional representation a preferred embodiment of the present invention.

FIG. 5 schematically illustrates in cross-sectional representation a completed integrated circuit device fabricated by the process of the present invention.

### DESCRIPTION OF THE PREFERRED EMBODIMENTS

The present invention provides a high quality liner layer and also minimizes the physical divot at the top corner of shallow trench isolation trenches by forming an in-situ silicon-rich oxide liner layer. Referring now more particularly to FIG. 1, there is shown a cross section of a partially completed integrated circuit device of the present invention. A semiconductor substrate 10, typically consisting of monocrystalline silicon, is provided. A plurality of isolation trenches are to be etched into the semiconductor substrate. For example, a pad silicon dioxide layer 12 is thermally grown over the substrate surface to a thickness of between about 80 and 120 Angstroms. A first etch stop layer 14 is deposited overlying the semiconductor substrate 10. The first etch stop layer 14 acts as a stop for the subsequent etching of the gap fill layer. The first etch stop layer 14 is preferably composed of silicon nitride and is deposited by low-pressure chemical vapor deposition (LPCVD). The first etch stop layer 14 is deposited to a thickness of between about 1500 and 2500 Angstroms. The first etch stop layer 14 and the semiconductor substrate 10 are etched to form trenches such as 15 for planned shallow trench isolations. The trenches are etched using a conventional etching process such as reactive ion etching (RIE). A thermal liner oxide layer 18 is grown within the trench 15 to a thickness of between about 100 and 200 Angstroms.

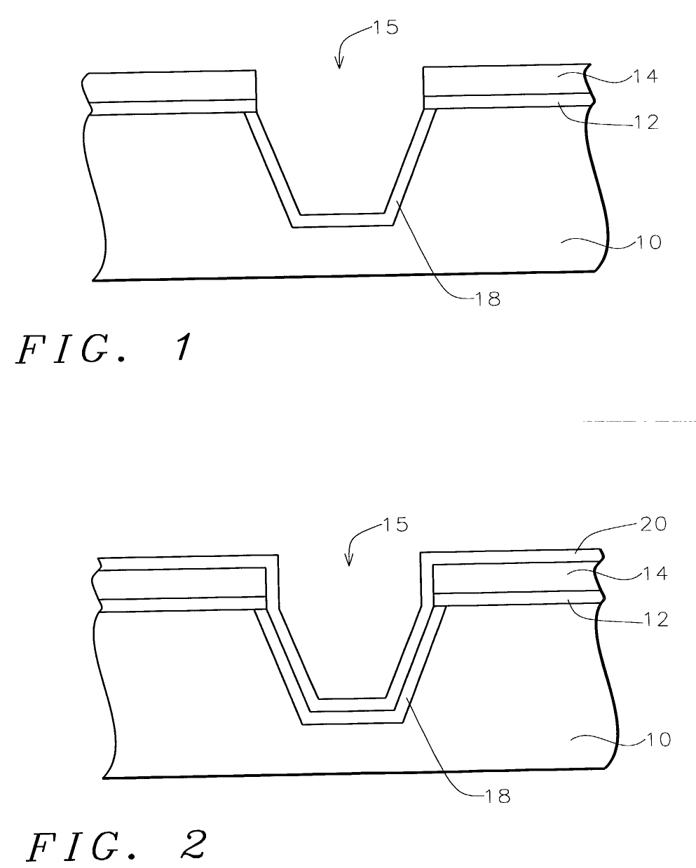

Referring now to FIG. 2, before the gap-fill process, an in-situ silicon-rich oxide (SRO) layer 20 is formed. The substrate is heated for about 25 to 60 seconds to a temperature of between about 300 and 450° C. SiH₄ and O₂ are flowed in a ratio of O₂:SiH₄ of between about 1.3:1 to 1.7:1 at a temperature of between about 400 and 650° C. The higher temperature results in a denser SRO film having a lower wet etch rate.

The reflective index of the SRO layer is controlled to be in the range of between about 1.50 to 1.70. It is very important that the reflective index (RI) be within the specified range. A RI lower than 1.50 would result in a high wet etch rate of the SRO. A too high RI of more than about 1.70 may cause leakage. The higher the RI, the more silicon-rich the film and the more dense the film. Gas flow rates must be adjusted to achieve the desired RI.

Bias power can be set to be between 0 and 800 watts for SRO deposition. This means that some sputtering is allowed during SRO deposition. The resulting SRO liner layer 20 has a thickness of between about 50 and 500 Angstroms.

Referring now to FIG. 3, the bulk gap-filling deposition 30 of high density plasma (HDP) oxide is deposited overlying the HDP SRO liner layer 20 and filling the trench.

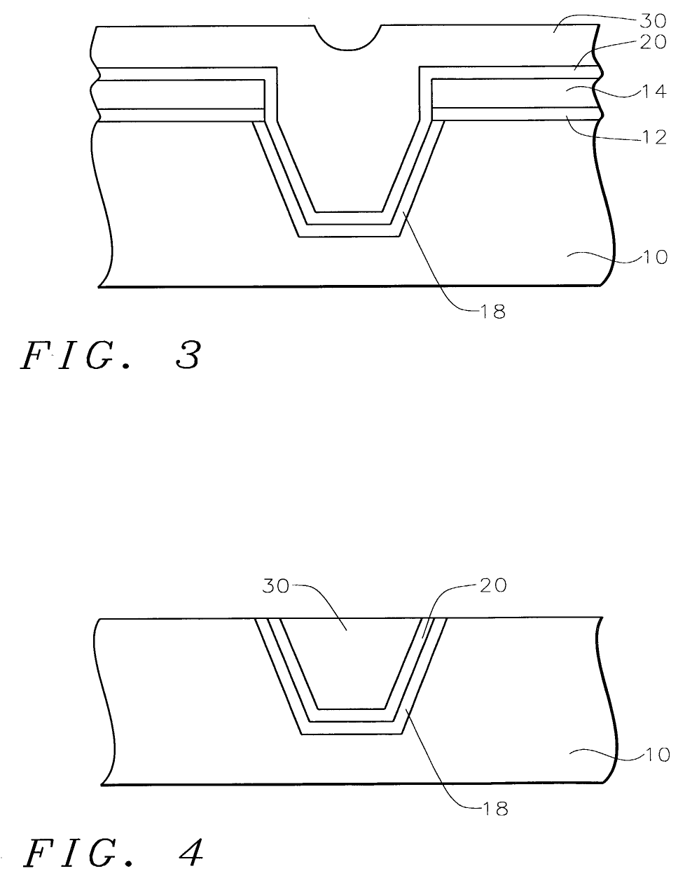

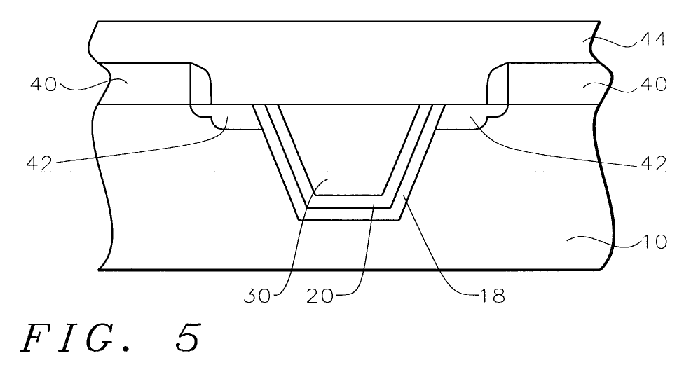

Now, the HDPCVD oxide layer 30 is planarized such as by chemical mechanical polishing to complete the shallow trench isolation, as shown in FIG. 4. This completes fabrication of the shallow trench isolation region. Now, the substrate is typically cleaned using DHF in preparation for forming semiconductor device structures on the substrate. For example, gate electrodes 40 and source and drain regions 42 may be formed in and on the semicondcutor substrate adjacent to the STI region 18/20/30, as shown in FIG. 5. A passivation layer 44 completes the integrated circuit device.

The DHF wet etch ratio of the SRO liner layer of the invention as compared to thermal oxide is between about 1.1:1 and 1.05:1. This ratio is significantly lower than the etch rate ratio of a typical HDP USG liner layer as compared to thermal oxide which is about 2.5:1. The wet etch rate ratio of the SRO liner layer of the present invention as compared to thermal oxide is even lower than that of the HDP bulk film 30 as compared to thermal oxide which is about 1.4:1. This means that the in-situ SRO liner layer of the present invention can minimize the physical divot that may appear at the top corners of the STI region during DHF cleaning processes.

The process of the present invention has been implemented and it has been found that using the SRO liner layer of the present invention in the STI process does not lead to gate leakage.

While the invention has been particularly shown and described with reference to the preferred embodiments thereof, it will be understood by those skilled in the art that various changes in form and details may be made without departing from the spirit and scope of the invention.

What is claimed is:

1. A method of forming a shallow trench isolation region in the manufacture of an integrated circuit device comprising:
etching an isolation trench into a substrate;
depositing a silicon-rich oxide liner layer overlying said substrate and within said isolation trench using a high density plasma chemical vapor deposition process (HDP-CVD); and
depositing an oxide layer overlying said silicon-rich oxide liner layer and filling said trench using said HDP-CVD process to complete fabrication of said shallow trench isolation region in said manufacture of said integrated circuit device.

2. The method according to claim 1 before said step of etching said isolation trench further comprising:
growing a pad oxide layer on said substrate;
depositing an etch stop layer overlying said pad oxide layer; and
patterning said etch stop layer and said pad oxide layer to form a mask for said step of etching said isolation trench.

3. The method according to claim 1 further comprising growing a thermal oxide liner layer within said isolation trench before said step of depositing said silicon-rich oxide liner layer within said isolation trench.

4. The method according to claim 1 wherein said step of depositing said silicon-rich oxide layer comprises flowing O₂ and SiH₄ gases in a ratio of O₂:SiH₄ of between about 1.3:1 and 1.7:1 at a temperature of between about 400 and 650° C.

5. The method according to claim 1 wherein said silicon-rich oxide layer has a reflective index of between about 1.50 to 1.70.

6. The method according to claim 3 wherein said silicon-rich oxide layer has a wet etch ratio with respect to said thermal oxide liner layer of between about 1.05:1 and 1.10:1.

7. The method according to claim 1 further comprising planarizing said shallow trench isolation region.

8. The method according to claim 1 further comprising fabricating semiconductor device structures in and on said substrate adjacent to said shallow trench isolation region.

9. A method of forming shallow trench isolation regions in the manufacture of an integrated circuit device comprising:
growing a pad oxide layer on the surface of a substrate;
depositing an etch stop layer overlying said pad oxide layer;
etching an isolation trench through said etch stop layer and said pad oxide layer into said substrate;
depositing a silicon-rich oxide liner layer overlying said substrate and within said isolation trench using a high density plasma chemical vapor deposition process (HDP-CVD); and
depositing an oxide layer overlying said silicon-rich oxide liner layer and filling said trench using said HDP-CVD process to complete fabrication of said shallow trench isolation region in said manufacture of said integrated circuit device.

10. The method according to claim 9 further comprising growing a thermal oxide liner layer within said isolation trench before said step of depositing said silicon-rich oxide liner layer within said isolation trench.

11. The method according to claim 9 wherein said step of depositing said silicon-rich oxide layer comprises flowing O₂ and SiH₄ gases in a ratio of O₂:SiH₄ of between about 1.3:1 and 1.7:1 at a temperature of between about 400 and 650° C.

12. The method according to claim 9 wherein said silicon-rich oxide layer has a reflective index of between about 1.50 to 1.70.

13. The method according to claim 10 wherein said silicon-rich oxide layer has a wet etch ratio with respect to said thermal oxide liner layer of between about 1.05:1 and 1.10:1.

14. The method according to claim 9 further comprising fabricating semiconductor device structures in and on said substrate adjacent to said shallow trench isolation region.

15. A method of forming shallow trench isolation regions in the manufacture of an integrated circuit device comprising:
growing a pad oxide layer on the surface of a substrate;
depositing an etch stop layer overlying said pad oxide layer;
etching an isolation trench through said etch stop layer and said pad oxide layer into said substrate;
growing a thermal oxide liner layer within said isolation trench;
depositing a silicon-rich oxide liner layer overlying said substrate and within said isolation trench overlying said thermal oxide layer using a high density plasma chemical vapor deposition process (HDP-CVD) and
depositing an oxide layer overlying said silicon-rich oxide liner layer and filling said trench using said HDP-CVD process to complete fabrication of said shallow trench isolation region in said manufacture of said integrated circuit device.

16. The method according to claim 15 wherein said step of depositing said silicon-rich oxide layer comprises flowing O₂ and SiH₄ gases in a ratio of O₂:SiH₄ of between about 1.3:1 and 1.7:1 at a temperature of between about 400 and 650° C. with bias power of 0 to 800 watts.

17. The method according to claim 15 wherein said silicon-rich oxide layer has a reflective index of between about 1.50 to 1.70.

18. The method according to claim 15 wherein said silicon-rich oxide layer has a wet etch ratio with respect to said thermal oxide liner layer of between about 1.05:1 and 1.10:1.

19. The method according to claim 15 further comprising planarizing said shallow trench isolation region.

20. The method according to claim 15 further comprising fabricating semiconductor device structures in and on said substrate adjacent to said shallow trench isolation region.
